(19) United States
(12) Patent Application Publication
(10) Pub. No.: US 2011/0290298 A1
(43) Pub. Date: Dec. 1, 2011

(54) SOLAR CELL, SOLAR MODULE, AND METHOD FOR WIRING A SOLAR CELL, AND CONTACT WIRE

(75) Inventors: Andreas Krause, Radebeul (DE); Martin Kutzer, Penig (DE); Olaf Storbeck, Dresden (DE); Alexander Fuelle, Kirchberg (DE)

(73) Assignee: SOLARWORLD INNOVATIONS GMBH, Freiberg (DE)

(21) Appl. No.: 13/116,041

(22) Filed: May 26, 2011

(30) Foreign Application Priority Data
Jun. 1, 2010 (DE) 10 2010 017 180.8

(51) Int. Cl. H01L 31/05; H01L 31/18; H01B 5/00; H01L 31/0224

(52) U.S. Cl. 136/244; 136/256; 438/57; 174/126.1; 257/E31.001

(57) ABSTRACT

In various exemplary embodiments, a solar cell is provided, including a layer structure having at least one photovoltaic layer; and a plurality of contact wires running on the surface of the layer structure. The contact wires are wire-bonded radially with respect to their axis onto the surface of the layer structure.

### CROSS-REFERENCE TO RELATED APPLICATION

This application claims priority to German Patent Application Serial No. 10 2010 017 180.8, which was filed Jun. 1, 2010, and is incorporated herein by reference in its entirety.

### TECHNICAL FIELD

Various exemplary embodiments relate to a solar cell, a solar module, and a method for wiring a solar cell, and a contact wire.

### BACKGROUND

A solar cell usually consists of a substrate having a front side and a rear side, wherein a contact structure or a plurality of contact structures is or are applied to at least one of the two sides. Typically, the contact structure has a width of at least 100 μm, while its thickness is only approximately 10 μm to 15 μm. A larger width of the contact structure leads to a reduction of the efficiency on account of the resulting increased shading, while a reduction of the width has the consequence that the line resistance of the contact structure is increased. Furthermore, the current of the individual contact structures is combined in so-called busbars, thereby causing a further shading of the front side area.

The interconnection of solar cells is generally effected by means of contact ribbons (also designated hereinafter as contact wires) soldered onto the busbars of the solar cell. In this case, the entire current is passed through the contact ribbons. In order to keep the resistance losses as low as possible, said contact ribbons need to have a certain total cross-sectional area. This has the consequence of a loss due to the shading on the front side. A further disadvantage is that the contact ribbon exerts stresses on the interface of paste (to put it another way soldering paste)—wafer during soldering, which can lead to the fracture of the solar cell.

Moreover, the conventional interconnection in a solar module, on account of ohmic losses and shading losses, leads to high power losses in the solar module. In the case of usually three contact ribbons, a relatively large amount of paste is required for screen printing in order to ensure the conductivity of the grid lines.

In order to create a good solar module, the contact structure(s) of the solar cell and the number and dimensioning of the contact ribbons should be optimized in combination with one another.

In the case of a multiplicity of thin contact wires to be positioned, one problem resides in the handling thereof and the positioning of the thin contact wires on the solar cell.

The patent specification DE 10 239 845 C1 describes a method in which the wires are fixed onto an optically transparent film with the aid of an optically transparent adhesive and are subsequently fixed onto the metallization of the solar cell. In this case, film and adhesive remain in the solar module. This implies relatively stringent requirements made of the adhesive and the film with regard to long-term stability and causes relatively high costs as a result.

A further disadvantage can be seen in the fact that relatively large amounts of cost-intensive screen printing paste are still required in the method in accordance with DE 10 239 845 C1.

Furthermore, EP 2 009 703 A1 describes a method for making contact with a solar cell in which a wire is axially wire-bonded onto a surface electrode. However, this requires a high space requirement and, particularly when wiring a multiplicity of contact wires, is very laborious and expensive and hence impracticable. Moreover, the embedding of the axially bonded solar cells proves to be difficult.

### SUMMARY

In various exemplary embodiments, a solar cell is provided, including a layer structure having at least one photovoltaic layer; and a plurality of contact wires running on the surface of the layer structure. The contact wires are wire-bonded radially with respect to their axis onto the surface of the layer structure.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a plan view of a solar cell with contact wires in accordance with one exemplary embodiment;

FIGS. 2A and 2B show electrically conductive point contacts in accordance with various exemplary embodiments;

FIGS. 3A and 3B show contact wires in accordance with various exemplary embodiments;

FIG. 4 shows a solar cell in accordance with one exemplary embodiment;

FIG. 5 shows a solar module in accordance with one exemplary embodiment;

FIG. 6 shows a flowchart illustrating a method for wiring a solar cell in accordance with one exemplary embodiment; and

FIG. 7 shows an arrangement with two rear-side contact solar cells in accordance with one exemplary embodiment.

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

In the following detailed description, reference is made to the accompanying drawings, which form part of this description and show for illustration purposes specific embodiments in which the invention can be implemented. In this regard, direction terminology such as, for instance, “at the top”, “at the bottom”, “at the front”, “at the back”, “front”, “rear”, etc., is used with reference to the orientation of the figure(s) described. Since components of embodiments can be positioned in a number of different orientations, the direction terminology serves for illustration purposes and is not restrictive in any way at all. It goes without saying that other embodiments can be used and structural or logical changes can be made, without departing from the scope of protection of the present invention. It goes without saying that the features of the various exemplary embodiments described herein can be combined with one another, unless specifically indicated otherwise. Therefore, the following detailed description should not be interpreted in a restrictive sense, and the scope of protection of the present invention is defined by the appended claims.

In the context of this description, the terms “connected” and “coupled” are used to describe both a direct and an indirect connection and also a direct or indirect coupling. In the figures, identical or similar elements are provided with identical reference symbols, insofar as this is expedient.

In various exemplary embodiments, less paste than in conventional solar modules is required for fixing the contact wires on the solar cell. In various exemplary embodiments, this leads to a reduction of costs in the context of producing a solar cell and a solar module. Moreover, an increase in power at the solar cell level and at the solar module level is achieved in various exemplary embodiments.

In various exemplary embodiments, a solar cell is provided, including a layer structure having at least one photovoltaic layer; and a plurality of contact wires running on the surface of the layer structure. The contact wires are wire-bonded radially with respect to their axis onto the surface of the layer structure.

Illustratively, in various exemplary embodiments, therefore, wiring of solar cells by means of wire bonding technology is provided, wherein the wire bonding is provided in such a way that the contact wires are wire-bonded radially with respect to their axis (relative to their longitudinal extent) onto the surface of the layer structure.

In various exemplary embodiments, a solar cell should be understood to mean a device which directly converts light energy (for example at least part of the light in the visible wavelength range of approximately 300 nm to approximately 1150 nm, for example sunlight), into electrical energy by means of the so-called photovoltaic effect.

In accordance with one development, a plurality of wire bonding connections are arranged on a contact wire running continuously on the surface, without the contact wire being interrupted by said wire bonding connections.

In various exemplary embodiments, the layer structure of the solar cell may have a base layer and an emitter layer, which form a pn junction region.

In various exemplary embodiments, the contact wires can be wire-bonded radially relative to the axis onto the surface of the emitter layer of the solar cell.

The layer structure may have a metallization electrically connected to the photovoltaic layer, wherein the contact wires may be wire-bonded radially with respect to the axis of the contact wires onto the surface of the metallization.

The metallization may have a multiplicity of electrically conductive point contacts.

The electrically conductive point contacts may have, in principle, any suitable shape, for example in plan view a circular shape or an elliptical shape or a polygonal shape. By way of example, in one development, at least one electrically conductive point contact of the multiplicity of electrically conductive point contacts may have a star-shaped structure. In various configurations, at least some electrically conductive point contacts of the multiplicity of electrically conductive point contacts may be connected to one another by means of a metallization.

Thus, by way of example, the metallization may have a plurality or multiplicity of contact structures, for example in the form of metallization lines or contact fingers.

In one configuration, the contact wires may be wire-bonded radially relative to the longitudinal axis of the contact wires onto the surface of the metallization.

The contact wires may be at least partly coated with a solderable material. The solderable material may include, for example, tin, nickel or silver.

In one configuration, the contact wires may be at least partly coated with gold or nickel or completely consist of gold or nickel.

Furthermore, the contact wires may have a polygonal cross section.

In yet another development, the layer structure may have a metallization on the front side and/or the rear side.

In yet another development, the layer structure may have an antireflection layer, wherein the antireflection layer may have openings at wire bonding connection locations provided.

In various exemplary embodiments, the solar cells of the solar module may have a square shape. In various exemplary embodiments, however, the solar cells of the solar module may also have a non-square shape. In these cases, the solar cells of the solar module may be formed, for example, by separating (for example cutting) and thus dividing one or a plurality of solar cell(s) (in terms of the shape thereof also designated as standard solar cell) to form a plurality of non-square or square solar cells. In various exemplary embodiments, in these cases provision may be made for performing adaptations of the contact structures in the standard solar cell; by way of example, rear-side transverse structures may additionally be provided.

In various exemplary embodiments, a solar module is provided, including a plurality of solar cells, wherein one solar cell or a plurality of solar cells of the solar module may be configured in accordance with one exemplary embodiment. At least some solar cells arranged in an adjacent fashion are electrically connected to one another by means of the contact wires.

The contact wires for electrically connecting two solar cells may be connected to the front side of a first solar cell of the respective two solar cells and to the rear side of a second solar cell of the respective two solar cells.

In various exemplary embodiments, a method for wiring a solar cell is provided. The method may include providing a layer structure having at least one photovoltaic layer; and wire bonding a plurality of contact wires onto a surface of the layer structure. The contact wires are wire-bonded radially with respect to their axis onto the surface of the layer structure.

In one configuration, providing the layer structure includes providing a base layer and an emitter layer, which form a pn junction region.

In yet another configuration, the contact wires are wire-bonded radially relative to the longitudinal axis of the contact wires onto the surface of the emitter layer.

Providing the layer structure may include applying a metallization by screen printing, dispensing, vapor deposition or deposition. In alternative exemplary embodiments, it is possible to use any other suitable method for applying the metallization.

The metallization can be formed with a multiplicity of electrically conductive point contacts such as have been described above, for example.

Before wire bonding, the contact wires may be at least partly coated with solderable material including, for example, tin, nickel or silver.

In one configuration, the contact wires may be at least partly coated with gold or nickel or completely consist of gold or nickel.

Providing the layer structure may furthermore include providing a rear-side metallization.

In one development, providing the layer structure includes providing an antireflection layer.

A plurality of wire bonding connections may be implemented on a contact wire running continuously on the surface, without the contact wire being interrupted by said wire bonding connections.

In various exemplary embodiments, a method for wiring a photovoltaic module including a plurality of solar cells is provided. The method may include wiring the plurality of solar cells in accordance with a method in accordance with one exemplary embodiment such as has been described above or else will be explained in even greater detail below. At least some solar cells of solar cells arranged adjacent to one another are electrically connected to one another by means of the contact wires.

One development provides for the contact wires for electrically connecting two solar cells to be connected to the front side of a first solar cell of the respective two solar cells and to the rear side of a second solar cell of the respective two solar cells.

One development provides for the solar cell to be a rear-side contact solar cell, configured in such a way that the contacts of the emitter layer and base layer are led onto the rear side of the solar cell. The contact wires are then used for electrically connecting the emitter contact of the first solar cell to the base contact of the adjacent second solar cell.

One particular advantage of various exemplary embodiments is manifested in the connection of rear-side contact cells. In this case, the emitter (otherwise usually front-side contact) and the base contact (otherwise usually rear-side contact) are both arranged on the rear side of the solar cell. By means of conventional connection technologies (soldering of solid soldering ribbons), stress is introduced into the solar cell. This often leads to severe warpage of the solar cells. That is prevented by the relatively cold or only locally heating bonding process and the flexible bonding wires.

In various exemplary embodiments, a contact wire for bonding onto a solar cell is provided, wherein the contact wire at least partly includes a coating with nickel, titanium or gold.

Illustratively, in various exemplary embodiments, an electrical contact-connection of solar cells is provided, in which one solar cell or a plurality of solar cells (for example including or consisting of silicon) is or are directly contact-connected by means of bonding. Furthermore, in various exemplary embodiments, it can be provided that specific point contacts (for example bonding structures or soldering pad structures) are present or are provided on the solar cell, which are connected to one another by means of (wire-)bonded contact wires.

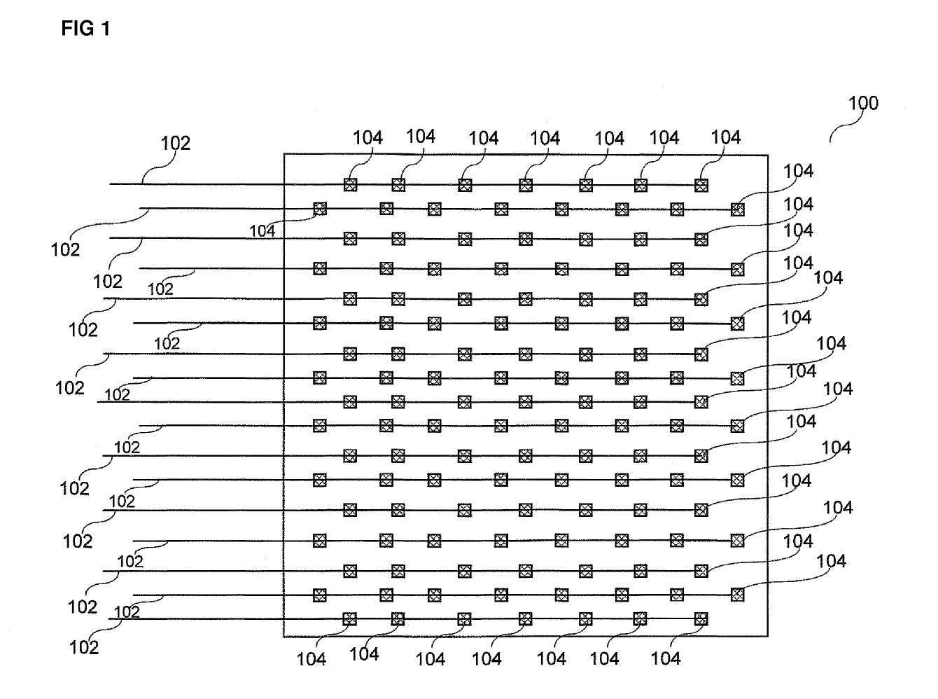

FIG. 1 shows a plan view of a solar cell 100 with contact wires 102 in accordance with one exemplary embodiment.

In various exemplary embodiments, solar cells which are formed for example in or on a wafer, for example a semiconductor wafer, may be electrically connected to one another and encapsulated for example as a solar module. A solar module may have a glass layer on its front side (that is to say the sun side, also designated as the emitter side), thereby enabling light that impinges on the solar module to be able to pass through the glass layer, while at the same time the semiconductor wafer or wafers is or are protected, for example against rain, hail, snow, etc.

In various exemplary embodiments, the solar cell 100 may have the following dimensions: a width in a range of approximately 10 cm to approximately 50 cm, a length in a range of approximately 10 cm to approximately 50 cm, and a thickness in a range of approximately 200 μm to approximately 300 μm.

In various exemplary embodiments, the solar cell 100 may have at least one photovoltaic layer (for example as part of a layer structure having one or a plurality of layers). The at least one photovoltaic layer may include or consist of a semiconductor material (such as, for example, silicon), a compound semiconductor material (such as, for example, a III-V compound semiconductor material such as, for example GaAs), a II-VI compound semiconductor material (such as, for example, CdTe), or a I-III-V compound semiconductor material (such as, for example CuInS₂). In various exemplary embodiments, the at least one photovoltaic layer may include or consist of an organic material. In various exemplary embodiments, the silicon may include or consist of monocrystalline silicon, polycrystalline silicon, amorphous silicon, and/or microcrystalline silicon. The at least one photovoltaic layer may include or consist of a junction structure such as, for example, a pn junction structure, a pin junction structure, a Schottky-like junction structure, and the like.

The rear side of the solar cell 100 may have a rear-side electrode. The rear-side electrode may include or consist of electrically conductive material, for example a metal such as, for example, one or a plurality of the following metals: Cu, Al, Au, Pt, Ag, Pb, Sn, Fe, Ni, Co, Zn, Ti, Mo, W, and/or Bi. The rear-side electrode may optionally be transparent. In various exemplary embodiments, the rear-side electrode may be structured.

Furthermore, an electrical contact-connection structure, for example implemented in the form of a plurality of metallization lines, to put it another way metallization conductors (for example in the form of contact fingers), may be provided on or above the front surface (in other words the uncovered surface) on the at least one photovoltaic layer. The metallization lines may extend substantially parallel to one another and/or at a distance from one another. However, it should be noted that the metallization lines alternatively run at an angle with respect to one another. In various exemplary embodiments, the metallization lines may be provided in a comb structure having a plurality of metal fingers extending substantially parallel to one another. In one implementation, the metallization lines are strip-shaped electrically conductive surface regions. Any other strip-shaped electrically conductive surface structure may be provided in alternative exemplary embodiments.

Thus, as shown in FIG. 1, in various exemplary embodiments, provision is made for the electrical contact-connection structure to be formed by electrically conductive point contacts 104.

To put it another way, in various exemplary embodiments, provision may be made of a solar cell 100 having a front-side guide fashioned in a point-type embodiment as the electrical contact-connection structure. The electrically conductive point contacts 104 are applied, for example, by screen printing or vapor deposition with subsequent firing (for example by means of a high-temperature step or a laser step) or a chemical or electrochemical deposition onto the surface (for example the emitter side) of the solar cell 100.

The individual electrically conductive point contacts 104 (also designated as bonding pads or soldering pads) may then be electrically contact-connected with contact wire 102 that are placed or positioned onto the surface of the solar cell; in this case, the contact wires 102 are applied to the solar cell 100 by a positioning and placement device (not illustrated in the figures); in various exemplary embodiments, fixing can be effected by means of soldering or wire bonding. In various exemplary embodiments, a plurality of contact wires 102 are arranged in a manner running onto the surface of the layer structure. The contact wires 102 are wire-bonded radially with respect to their axis onto the surface of the layer structure of the solar cell 102.

Illustratively, in the positioning and placement device or separately therefrom, a wire bonding device that is conventional per se can be provided, which is designed in such a way that the contact wires 102 may be wire-bonded radially with respect to their axis on the surface of the layer structure of the solar cell 102.

Illustratively, in various exemplary embodiments, therefore, wiring of solar cells by means of wire bonding technology is provided, wherein the wire bonding is provided in such a way that the contact wires 102 are wire-bonded radially with respect to their axis (relative to their longitudinal extent), onto the surface of the layer structure.

In various exemplary embodiments, a solar cell should be understood to mean a device which directly converts light energy (for example at least part of the light in the visible wavelength range of approximately 300 nm to approximately 1150 nm, for example sunlight), into electrical energy by means of the so-called photovoltaic effect.

As illustrated in FIG. 1, in various exemplary embodiments, the contact wires 102 are wire-bonded with a plurality of, for example with all, point contacts 104 along the longitudinal extent of the contact wires 102 onto the contact-connection structure, for example the point contacts 104, wherein the contact-connection structure forms, for example, a metallization of the solar cell 100. Consequently, in the case of at least a portion or in the case of each of the contact wires 102, a plurality of wire bonding connections are arranged on the respective contact wire 102 running continuously on the surface of the layer structure of the solar cell 102, without the respective contact wire 102 being interrupted by these wire bonding connections. Consequently, a current flow through the entire respective contact wire 102 is still made possible from one end of the respective contact wire 102 to the other end thereof.

In various exemplary embodiments, the layer structure of the solar cell 100 has a base layer and an emitter layer, which form a pn junction region for generating electrical energy.

As will be explained in even greater detail below, in various exemplary embodiments, the contact wires 102 are wire-bonded radially relative to the axis onto the surface of the emitter layer of the solar cell 100.

During the wire bonding in accordance with various exemplary embodiments, a very thin bonding wire (for example having a diameter d<180 μm) is fixedly connected (microwelded) to the contact area, that is to say the surface of the solar cell 100, for example by means of an ultrasonic pulse issuing from an ultrasonic sonotrode incorporated in a wire guide head of the positioning and placement device, and by means of slight pressure. The topmost oxide layer on the bonding wire and the bonding pad (that is to say generally the contact-connection structure, for example the point contacts 104) may be destroyed by means of the energy introduced by the ultrasonic pulse. The interdiffusion thus initialized gives rise to a eutectic composed of the respective wire material and the substrate material (for example the material of the emitter layer).

Depending on the requirement made of the substrate (for example made of the emitter layer of the solar cell) or the structures to be connected by bonding, various bonding methods/bonding techniques may be used, such as e.g. wedge-wedge bonding, ball-wedge bonding, thick-wire-wedge bonding or ribbon bonding. Thick-wire-wedge bonding, or a construction based thereon, is well suited since the wire diameter of the bonding wires that is used in this technique may be processed well in a range of, for example, 100 μm to 500 μm.

As has been described above, in order to produce a good solar module it is desirable for the contact structure(s) of the solar cell 100 and the number and dimensioning of the contact ribbons, to put it another way the contact wires 102, to be optimized in combination with one another.

In various exemplary embodiments it has been found that, in this case, an optimum arises for many (for example number n>30) thin (for example diameter d<250 μm) contact wires 102 that run parallel. It should furthermore be expected that on account of the punctiform fixing of the contact wires 102 on the solar cell 100, lower mechanical stresses will be built up as a result of the different coefficients of thermal expansion of contact wire 102 and solar cell 100. Furthermore, by means of various exemplary embodiments, the costs for the contact structure(s) of the solar cell 100 may be considerably reduced by comparison with a customary contact structure.

In various exemplary embodiments, the contact wires 102 may have a plurality or multiplicity of contact wires 102, for example approximately three contact wires 102 to approximately 90 contact wires 102, for example approximately five contact wires 102 to approximately 50 contact wires 102, for example approximately 20 contact wires 102.

In various exemplary embodiments, thin contact wires 102 are provided, wherein the contact wires 102 have for example a diameter of less than 400 μm, for example a diameter of less than 350 μm, for example a diameter of less than 300 μm, for example a diameter of less than 250 μm. The contact wires 102 may run substantially parallel to one another, alternatively at an angle with respect to one another. The contact wires 102 may be designed for collecting and transferring electrical energy, for example electric current, which is generated by the respective solar cell 102 for example by the respective at least one photovoltaic layer.

The contact wires 102 may include or consist of electrically conductive material, for example metallically conductive material, which may contain or may consist of one or more of the following metals: Cu, Al, Au, Pt, Ag, Pb, Sn, Fe, Ni, Co, Zn, Ti, Mo, W, and/or Bi. The contact wires 102 may include or consist of a metal selected from a group consisting of: Cu, Au, Ag, Pb and Sn.

The contact wires 102 may be at least partly coated with a solderable material. The solderable material may include, for example, tin, nickel or silver.

In one configuration, the contact wires 102 (which are used directly as bonding wires in various exemplary embodiments) may be at least partly coated with gold or nickel or completely consist of gold or nickel.

The contact wires 102 may generally have any desired cross section, such as, for example, a round cross section, an oval cross section, a triangular cross section, a rectangular cross section (for example a square cross section), or a cross section of any other polygonal shape. The contact wires 102 may furthermore have a structured surface.

The electrically conductive point contacts 104 may have, in principle, any suitable shape, for example in plan view a circular shape or an elliptical shape or a polygonal shape.

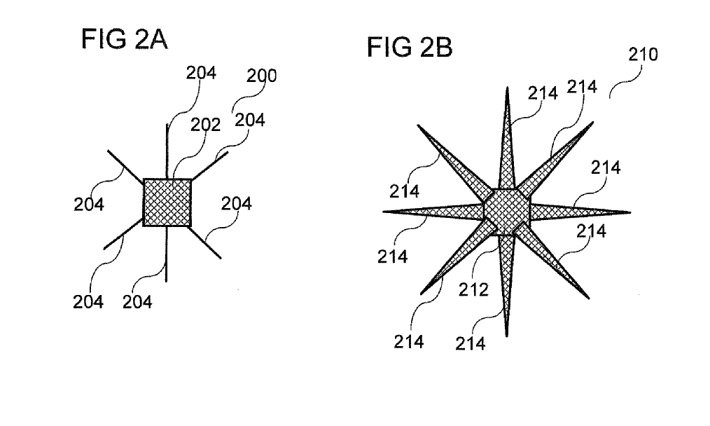

In order that the electrical charge carriers generated between the electrically conductive point contacts 104 are collected with lower losses, the electrically conductive point contacts 104 may be supplemented by current collecting structures. Examples are presented in FIG. 2A and FIG. 2B.

By way of example, in various exemplary embodiments, at least one electrically conductive point contact 104 of the multiplicity of electrically conductive point contacts 104 may have a star-shaped structure, as illustrated for example in FIG. 2A and FIG. 2B. In various configurations, at least some electrically conductive point contacts 104 of the multiplicity of electrically conductive point contacts 104 may be connected to one another by means of a metallization. This gives rise to an interlinking by means of which losses upon faulty contact-connection of a contact wire 102 may be reduced.

FIG. 2A shows an implementation of one electrically conductive contact point 200 in accordance with various exemplary embodiments having an electrically conductive central region 202, which, in principle, has any desired shape, for example a rectangular shape. Furthermore, the central region 202 is electrically coupled to electrically conductive line-shaped current collecting structures 204 additionally provided, which, in accordance with various exemplary embodiments, extent radially from the center of the central region 202. The current collecting structures 204 may be formed from the same or a different electrically conductive material with respect to the central region 202.

FIG. 2B shows an implementation of another electrically conductive point contact 210 in accordance with various exemplary embodiments having an electrically conductive central region 212 which, in principle, has any desired shape, for example a rectangular shape. Furthermore, the central region 212 is electrically coupled to electrically conductive current collecting structures 214 additionally provided, which, in accordance with various exemplary embodiments, extend radially from the center of the central region 212. The current collecting structures 214 may be embodied in a manner tapering outward relative to the central region 212, such that the width of a respective current collecting structure 214 at the end thereof is smaller than the width of the current collecting structure 214 at the end coupled to the central region 202.

In various exemplary embodiments, the layer structure of the solar cell 100 may have an antireflection layer (for example applied on the surface of the emitter side of the solar cell 100). In various exemplary embodiments, the antireflection layer may be applied before the wiring of the solar cell 100 (for example by means of a deposition method, for example by means of a deposition method from the gas phase (Chemical Vapor Deposition, CVD)). Alternatively, in various exemplary embodiments, the antireflection layer may be applied after the wiring of the solar cell 100 (for example may be sputtered by means of a sputtering method).

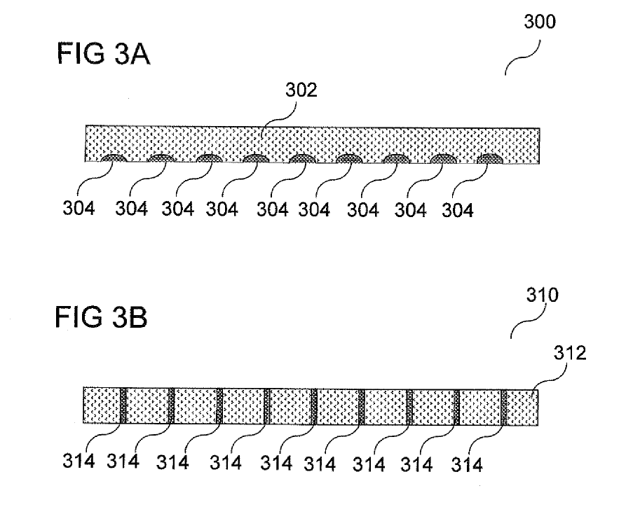

FIG. 3A and FIG. 3B show contact wires in accordance with various exemplary embodiments. These contact wires may be provided for example in various exemplary embodiments in which, in the case of the solar cell 100, no contact-connection structure is provided and, therefore, for example, no electrically conductive point contacts 104 are provided either. In these exemplary embodiments, it is possible to provide a direct mechanical and electrical connection of the solar cell (for example silicon solar cell), with one contact wire or with a plurality of contact wires. In these exemplary embodiments, the metallization of the solar cell may be dispensed with, and the electrical contact is produced by means of wire bonding with the photovoltaic layer of the solar cell.

One particularly suitable material for the direct contact-connection of silicon is gold in various exemplary embodiments. At a temperature as low as approximately 400° C., a eutectic forms in the case of gold. Consequently, in various exemplary embodiments, the contact wires 102 include gold (for example on a part of the surface or the entire surface of the contact wires 102). Alternatively, in various exemplary embodiments, contact wires 102 consist of gold. In various exemplary embodiments, the contact wires 102 may also include or consist of some other suitable metal or some other suitable metal alloy which, for example, form a eutectic at a sufficiently low temperature.

As illustrated in FIG. 3A, in various exemplary embodiments, a contact wire 300 includes copper, which forms the body 302 or core of the contact wire 300 and which may be coated with some other metal, for example nickel or some other suitable metal. In various exemplary embodiments, depressions 304 are formed in the body 302 of the contact wire 300, which depressions can be filled with gold. The depressions 304 may have a depth into the body 302 of the contact wire 300 in a range of approximately 50 nm to approximately 400 nm, for example in a range of approximately 75 nm to approximately 300 nm, for example in a range of approximately 100 nm to approximately 200 nm.

As illustrated in FIG. 3B, in various exemplary embodiments, a contact wire 310 includes copper, which forms the body 312 or core of the contact wire 310 and which may be coated with some other metal, for example nickel or some other suitable metal. In various exemplary embodiments, holes (for example having a polygonal or circular cross section) 304 are provided in the body 312 of the contact wire 310, which holes may be filled with gold. The radius of the holes 314 in the body 312 of the contact wire 310 may be in a range of approximately 50 nm to approximately 400 nm, for example in a range of approximately 75 nm to approximately 300 nm, for example in a range of approximately 100 nm to approximately 200 nm.

The use of contact wires composed of copper, for example partly or completely coated with nickel and/or gold, reduces the costs for the contact wires and therefore also for a solar cell in accordance with various exemplary embodiments.

In various exemplary embodiments, wire bonding contacts are formed between the contact wires (once again radially with respect to the axis thereof) and an antireflection layer of the layer structure. In one exemplary embodiment, in which the antireflection layer includes silicon nitride (Si₃N₄), the material to be bonded may include nickel and/or titanium (to put it another way, the contact wires to be wire-bonded include nickel and/or titanium, are coated therewith or consist thereof).

Consequently, in various exemplary embodiments, it is provided that the bonding contact is not formed between a respective contact wire and the silicon of the solar cell 100, but rather is formed between a respective contact wire (that is to say, for example, nickel and/or titanium) and the antireflection layer (for example composed of silicon nitride (Si₃N₄)). For this purpose, by way of example, a respective copper contact wire is coated with nickel, titanium or a nickel-titanium bilayer. In this case, the ohmic contact arises, for example, by means of the siliciding of the topmost silicon layer or by means of the silicon surface being brought into contact with the respective contact wire.

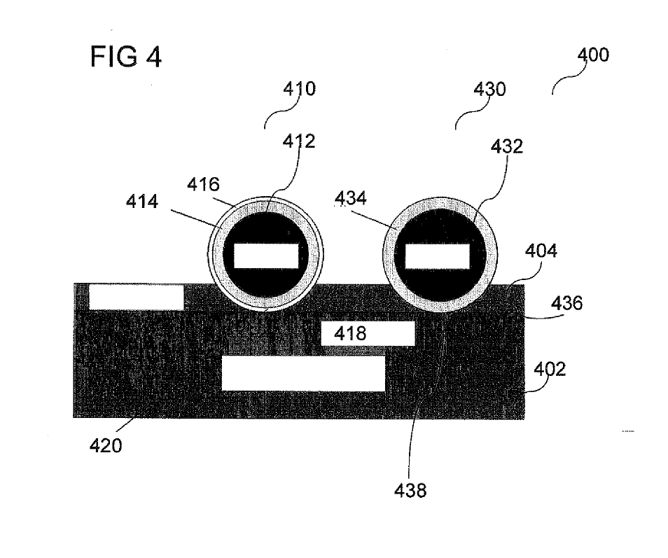

FIG. 4 shows a solar cell 400 in accordance with one exemplary embodiment.

The solar cell 400 has a layer structure having a photovoltaic layer 402 and an antireflection layer 404 (for example composed of silicon nitride (Si₃N₄)) applied on the photovoltaic layer 402. Furthermore, two different exemplary embodiments of contact wires 410, 430 are illustrated in cross-sectional view.

A contact wire 410 in accordance with one exemplary embodiment is formed by a copper core 412 and also a sheathing, wherein the sheathing includes a diffusion bather layer, for example a nickel layer 414, applied on the surface of the copper core 412. In addition, the contact wire may include a titanium layer 416 applied on the nickel layer 414. Reference symbol 418 designates a wire bonding zone between the topmost exposed region—situated in physical contact with the antireflection layer 404—of the layer of the sheathing of the contact wire 410 and the antireflection layer 404. Furthermore, reference symbol 420 designates an electrical contact region between the contact wire 410 and the silicon layer 402 (or, if appropriate, if present, a silicide on the silicon layer 402).

A contact wire 430 in accordance with another exemplary embodiment is formed by a copper core 432 and also a single-layer sheathing (for example composed of a single metal layer or metal alloy layer), wherein the single-layer sheathing includes a single layer composed of a metal, for example a nickel layer 434, applied on the surface of the copper core 432. Reference symbol 436 designates a wire bonding zone between the exposed region—situated in physical contact with the antireflection layer 404—of the single-layer sheathing of the contact wire 430 and the antireflection layer 404. Furthermore reference symbol 438 designates an electrical contact region between the contact wire 430 and the silicon layer 402 as photovoltaic layer (or, if appropriate, if present, a silicide on the silicon layer 402).

In various exemplary embodiments, the sheathing of the contact wire core may also have more than two layers.

Consequently, in the exemplary embodiments illustrated in FIG. 4, the antireflection layer 404 has openings at the wire bonding connection locations provided. The openings may be formed using all structuring methods known per se.

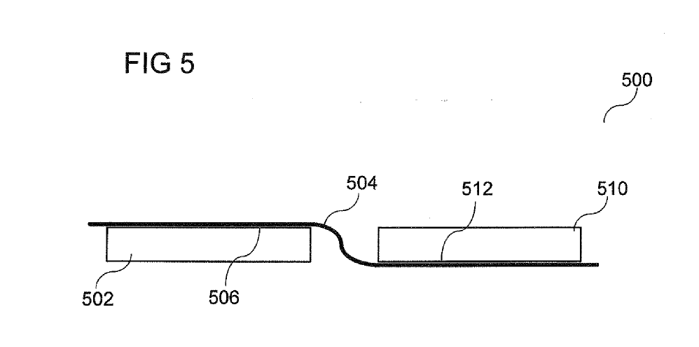

The interconnection of the plurality of solar cells 100 to form a solar module 500 (cf. FIG. 5) by means of the contact wires 102, 504 leads to solar cell strings of varying length of, for example, 10 solar cells (in alternative exemplary embodiments, a solar cell string may have a length of three solar cells to 40 solar cells, for example a length of five solar cells to 15 solar cells), and the solar cell strings may have different arrangements in the solar module (they can be arranged e.g. in a longitudinal direction or in a transverse direction). FIG. 5 illustrates, for reasons of comprehensibility of the description, a solar cell string of the solar module 500 having two solar cells, a first solar cell 502 and a second solar cell 510.

The contact wires 504 for electrically connecting two solar cells 502, 510 may be connected to the front side 506 of the first solar cell 502 of the respective two solar cells 502, 510 and to the rear side 512 of the second solar cell 510 of the respective two solar cells 502, 510. The solar cells 502, 510 are connected to the contact wires 504 in the manner described above in accordance with the various exemplary embodiments.

Of course, the contact may also be embodied as a point contact as described previously in the other exemplary embodiments.

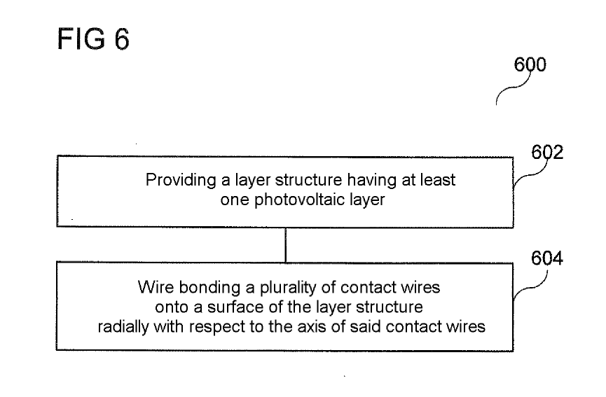

FIG. 6 shows a flowchart 600 illustrating a method for wiring a solar cell in accordance with one exemplary embodiment.

The method may include, in 602, providing a layer structure having at least one photovoltaic layer, and, in 604, wire bonding a plurality of contact wires onto a surface of the layer structure. The contact wires are wire-bonded radially with respect to their axis onto the surface of the layer structure.

In one configuration, providing the layer structure includes providing a base layer and an emitter layer, which form a pn junction region. In yet another configuration, the contact wires are wire-bonded radially relative to the contact wires onto the surface of the emitter layer. Providing the layer structure may include applying a metallization by screen printing, dispensing, vapor deposition or deposition. In alternative exemplary embodiments, it is possible to use any other suitable method for applying the metallization. The metallization may be formed with a multiplicity of electrically conductive point contacts such as have been described above, for example. Before wire bonding, the contact wires may be at least partly coated with solderable material including, for example, tin, nickel or silver. In one configuration, the contact wires may be at least partly coated with gold or nickel or completely consist of gold or nickel. Providing the layer structure may furthermore include providing a rear-side metallization. In one development, providing the layer structure includes providing an antireflection layer.

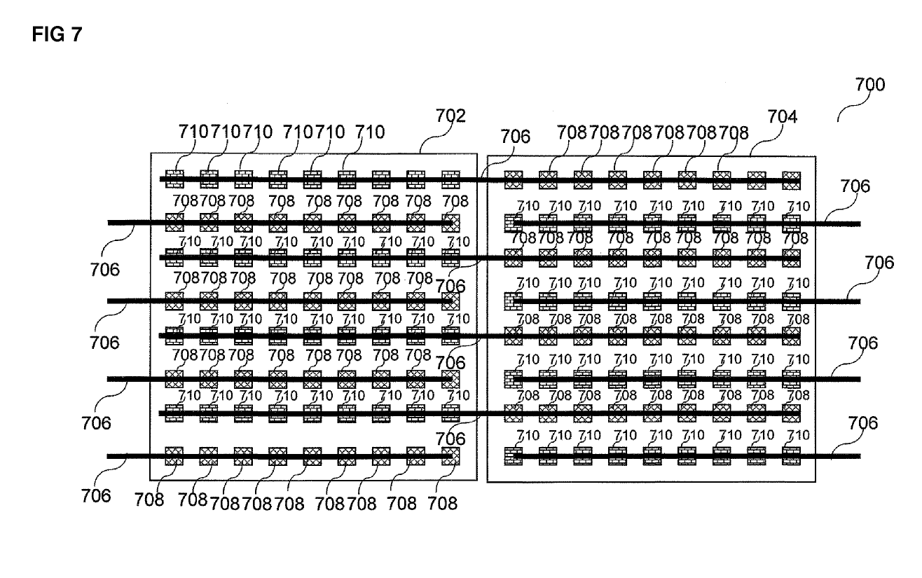

FIG. 7 shows an arrangement 700 with two rear-side contact solar cells 702, 704, which are wired by means of the technology described above.

The solar cells 702, 704 may be embodied substantially in the same way as the solar cell 100 as shown in FIG. 1 and described in detail above. However, a difference between the solar cells 702, 704 and the solar cell 100 illustrated in FIG. 1 may be seen in the fact that the solar cells 702, 704 each have a rear-side metallization.

The rear side of the solar cell 702, 704 may have a rear-side metallization or rear-side electrode. The rear-side metallization or rear-side electrode may include or consist of electrically conductive material, for example a metal such as, for example, one or a plurality of the following metals: Cu, Al, Au, Pt, Ag, Pb, Sn, Fe, Ni, Co, Zn, Ti, Mo, W, and/or Bi. The rear-side metallization or rear-side electrode may optionally be transparent. In various exemplary embodiments, the rear-side electrode may be structured.

Furthermore, an electrical contact-connection structure, for example implemented in the form of a plurality of metallization lines, to put it another way metallization conductors (for example in the form of contact fingers), may be provided on or above the front surface (in other words the uncovered surface) on the at least one photovoltaic layer. The metallization lines may extend substantially parallel to one another and/or at a distance from one another. However, it should be noted that the metallization lines alternatively run at an angle with respect to one another. In various exemplary embodiments, the metallization lines may be provided in a comb structure having a plurality of metal fingers extending substantially parallel to one another. In one implementation, the metallization lines are strip-shaped electrically conductive surface regions. Any other strip-shaped electrically conductive surface structure may be provided in alternative exemplary embodiments.

Thus, as shown in FIG. 7, in various exemplary embodiments, it is provided that the electrical contact-connection structure is formed by electrically conductive point contacts 708, 710, for example by base contacts 708 and emitter contacts 710.

To put it another way, in various exemplary embodiments, provision may be made of a solar cell 702, 704 having a rear-side grid fashioned in a point-type embodiment as the electrical contact-connection structure. The electrically conductive point contacts 708, 710, for example base contacts 708 and emitter contacts 710, are applied, for example, by screen printing or vapor deposition with subsequent firing (for example by means of a high-temperature step or a laser step) or a chemical or electrochemical deposition onto the surface (for example the emitter side) of the solar cell 702, 704.

The individual electrically conductive point contacts 708, 710, for example base contacts 708 and emitter contacts 710 (also designated as bonding pads or soldering pads), may then be electrically contact-connected with contact wires 706 that are placed or positioned onto the surface of the solar cell; in this case, the contact wires 706 are applied to the solar cell 700, 702 by a positioning and placement device (not illustrated in the figures); in various exemplary embodiments, fixing may be effected by means of soldering or wire bonding. In various exemplary embodiments, a plurality of contact wires 706 are arranged in a manner running onto the surface of the layer structure. The contact wires 706 are wire-bonded radially with respect to their axis onto the surface of the layer structure of the solar cell 702, 704.

Illustratively, in the positioning and placement device or separately therefrom, a wire bonding device that is conventional per se may be provided, which is designed in such a way that the contact wires 706 may be wire-bonded radially with respect to their axis on the surface of the rear side of the layer structure of the solar cell 702, 704.

Illustratively, in various exemplary embodiments, therefore, rear-side wiring of solar cells by means of wire bonding technology is provided, wherein the wire bonding is provided in such a way that the contact wires 706 are wire-bonded radially with respect to their axis (relative to their longitudinal extent), onto the surface of the rear side of the layer structure.

The contact wires 706 illustrated in FIG. 7 may be embodied in the same way as the contact wires 102 illustrated in FIG. 1.

The contact wires 706 may be wire-bonded with a plurality of, for example with all, point contacts 708, 710 along the longitudinal extent of the contact wires 706 onto the contact-connection structure, for example the point contacts 708, 710, wherein the contact-connection structure forms, for example, a metallization of the solar cell 702, 704. Consequently, in the case of at least a portion or in the case of each of the contact wires 706, a plurality of wire bonding connections are arranged on the respective contact wire 706 running continuously on the surface of the rear side of the layer structure of the solar cell 702, 704, without the respective contact wire 706 being interrupted by these wire bonding connections. Consequently, a current flow through the entire respective contact wire 706 is still made possible from one end of the respective contact wire 706 to the other end thereof. In various exemplary embodiments, in each case the base contacts 708 of a solar cell (for example of the first solar cell 702) can be or have been contact-connected by means of a respective contact wire 706 to emitter contacts 710 of a solar cell (for example the second solar cell 704) positioned directly adjacent thereto. Correspondingly, in various exemplary embodiments, in each case the emitter contacts 710 of a solar cell (for example of the first solar cell 702) can be or have been contact-connected by means of a respective contact wire 706 to base contacts 708 of a solar cell (for example the second solar cell 704) positioned directly adjacent thereto. It is thus possible to form, for example, a series circuit of the solar cells 702, 704 for forming a solar module.

Depending on the requirement made of the substrate (for example made of the emitter layer of the solar cell) or the structures to be connected by bonding, various bonding methods/bonding techniques can be used, such as e.g. wedge-wedge bonding, ball-wedge bonding, thick-wire-wedge bonding or ribbon bonding. Thick-wire-wedge bonding, or a construction based thereon, is well suited since the wire diameter of the bonding wires that is used in this technique can be processed well in a range of, for example, 100 μm to 500 μm.

As has been described above, in order to produce a good solar module it is desirable for the contact structure(s) of the solar cell 702, 704 and the number and dimensioning of the contact ribbons, to put it another way the contact wires 102, to be optimized in combination with one another.

The electrically conductive point contacts 708, 710 may have, in principle, any suitable shape, for example in plan view a circular shape or an elliptical shape or a polygonal shape.

In order that the electrical charge carriers generated between the electrically conductive point contacts 708, 710 are collected with lower losses, the electrically conductive point contacts 708, 710 can be supplemented by current collecting structures.

Examples are presented in FIG. 2A and FIG. 2B and described above in detail.

In further exemplary embodiments, providing the layer structure includes producing a rear-side contact cell, for example using a Metal-Wrap-Through (MWT) or Emitter-Wrap-Through (EWT) technology.

A plurality of wire bonding connections may be implemented on a contact wire running continuously on the surface, without the contact wire being interrupted by these wire bonding connections.

In various exemplary embodiments, a method for wiring a photovoltaic module including a plurality of solar cells is provided. The method may include wiring the plurality of solar cells in accordance with a method in accordance with one exemplary embodiment such as has been described above. At least some solar cells of solar cells arranged adjacent to one another are electrically connected to one another by means of the contact wires. One development provides for the contact wires for electrically connecting two solar cells to be connected to the front side of a first solar cell of the respective two solar cells and to the rear side of a second solar cell of the respective two solar cells.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A solar cell, comprising:
a layer structure having at least one photovoltaic layer; and
a plurality of contact wires running on the surface of the layer structure;
wherein the contact wires are wire-bonded radially with respect to their axis onto the surface of the layer structure.

2. The solar cell as claimed in claim 1,
wherein a plurality of wire bonding connections are arranged on a contact wire running continuously on the surface, without the contact wire being interrupted by said wire bonding connections.

3. The solar cell as claimed in claim 1,
wherein the layer structure has a metallization electrically connected to the photovoltaic layer; and
wherein the contact wires are wire-bonded radially with respect to their axis onto the surface of the metallization.

4. The solar cell as claimed in claim 3,
wherein the metallization has a multiplicity of electrically conductive point contacts.

5. The solar cell as claimed in claim 1,
wherein the contact wires are at least partly coated with a solderable material comprising, in particular, tin, nickel or silver.

6. The solar cell as claimed in claim 1,
wherein the contact wires are at least partly coated with at least one of gold and nickel or completely consist of at least one of gold and nickel.

7. The solar cell as claimed in claim 1,
wherein the contact wires have a polygonal cross section.

8. The solar cell as claimed in claim 1,
wherein the layer structure has an antireflection layer;
wherein the antireflection layer has openings at wire bonding connection locations provided.

9. The solar cell as claimed in claim 1,
wherein the solar cell has a non-square shape.

10. A solar module,
comprising a plurality of solar cells, each solar cell comprising:
a layer structure having at least one photovoltaic layer; and
a plurality of contact wires running on the surface of the layer structure;
wherein the contact wires are wire-bonded radially with respect to their axis onto the surface of the layer structure.
wherein at least some solar cells arranged in an adjacent fashion are electrically connected to one another by means of the contact wires.

11. A method for wiring a solar cell, the method comprising:
providing a layer structure having at least one photovoltaic layer; and
wire bonding a plurality of contact wires onto a surface of the layer structure;
wherein the contact wires are wire-bonded radially with respect to their axis onto the surface of the layer structure.

12. The method as claimed in claim 11,
wherein providing the layer structure comprises applying a metallization.

13. The method as claimed in claim 12,
wherein providing the layer structure comprises applying a metallization by a process selected from a group consisting of: screen printing, dispensing, vapour deposition; and deposition.

14. The method as claimed in claim 11,
wherein the contact wires are wire-bonded radially with respect to their axis onto the surface of the metallization.

15. The method as claimed in claim 11,
wherein a plurality of wire bonding connections are implemented on a contact wire running continuously on the surface, without the contact wire being interrupted by said wire bonding connections.

16. A solar cell contact wire for bonding onto a solar cell,
wherein the solar cell contact wire at least partly comprises a coating with a material selected from a group consisting of nickel, titanium or gold.
